(19) United States
(12) Patent Application Publication
(10) Pub. No.: US 2024/0297477 A1
(43) Pub. Date: Sep. 5, 2024

(54) WAVELENGTH LOCKER FOR DISTRIBUTED FEEDBACK TUNABLE LASER

(71) Applicant: NeoPhotonics Corporation, San Jose, CA (US)

(72) Inventors: Jiann-Chang Lo, Cupertino, CA (US); Vinson Mar, San Ramon, CA (US)

(21) Appl. No.: 18/116,365

(22) Filed: Mar. 2, 2023

(51) Int. Cl. H01S 5/00; H01S 5/024; H01S 5/06; H01S 5/0687

(52) U.S. Cl. CPC H01S 5/0078; H01S 5/02415; H01S 5/0612; H01S 5/0687

(57) ABSTRACT

A tunable distributed feedback (DFB) laser unit comprises:
a thermo-electric cooler;
a tunable DFB laser diode; and
an optical filter chip comprising:
   a tunable optical filter;
   a first optical splitter with an optical tap and an output path, and
   a first photodetector configured to receive light from the optical tap from the first optical splitter and to monitor output intensity from the tunable optical filter;
wherein the tunable DFB laser diode is supported on the thermo-electric cooler and wherein the light from the tunable laser diode or a fraction thereof is directed through the tunable optical filter.

The tunable DFB laser unit can be used in a method for wavelength locking the DFB laser.

### FIELD OF THE DISCLOSURE

Embodiments of the disclosure are directed to wavelength locking semiconductor lasers. Specifically, various embodiments are directed to a semiconductor filter chip configured for wavelength control to keep a tunable laser diode locked to a target wavelength.

### BACKGROUND

The wavelength stability of laser diodes underpins many applications in photonics which often have strict stability requirements for short-term and long-term operation. For example, in telecommunications applications using dense wavelength division multiplexing (DWDM), lasers may be restricted to operation within the International Telecommunication Union (ITU) grid. This requires operating in the range 1530-1625 nm with a channel spacing ranging from 10 GHz to 100 GHz, centered with a frequency precision of Δν=±1.5 GHz (Δλ=±12 pm). In other applications, such as high-resolution gas spectroscopy, a laser's emission wavelength is scanned across a narrow gas absorption line to measure the gas concentration. The wavelength drift of the laser must be much smaller than the gas linewidth, which for methane at λ=1651 nm is Δλ=40 pm full width half maximum.

Laser diodes such as distributed feedback (DFB) lasers are often used in these applications, where the emission wavelength is a function of the injection current and laser operating temperature. Thus, if the injection current is fixed and the temperature of the laser's active region is controlled, the emitted wavelength should remain constant. However, operating temperature is affected by the external package temperature, junction heating and thermal gradients within the package. Even with good thermal package design, active wavelength stabilization is desirable.

### SUMMARY

According to embodiments of the present disclosure, tunable distributed feedback (DFB) laser unit comprising
a thermo-electric cooler;
a tunable DFB laser diode; and
an optical filter chip comprising:
   a tunable optical filter;
   a first optical splitter with an optical tap and an output path, and
   a first photodetector configured to receive light from the optical tap from the first optical splitter and to monitor output intensity from the tunable optical filter;
wherein the tunable DFB laser diode is supported on the thermo-electric cooler and wherein the light from the tunable laser diode or a fraction thereof is directed through the tunable optical filter.

In further aspects, the invention pertains to a wavelength locking tunable distributed feedback (DFB) laser unit comprising:
a thermo-electric cooler;
a tunable DFB laser diode; and
an optical filter chip comprising:
   a tunable optical filter;
   a first temperature sensor configured to sense a filter temperature for the tunable optical filter;
   a first optical splitter with an optical tap and an output path, and
   a first photodetector configured to receive light from the optical tap from the first optical splitter and to monitor output intensity from the tunable optical filter; and
a logical controller coupled with the tunable DFB laser diode and the optical filter chip, wherein the optical filter chip is configured to provide one or more of the filter temperature and output intensity from the tunable optical filter to the logical controller as feedback for control of a laser frequency of the tunable DFB laser diode to match an optical filter frequency; and
wherein the tunable DFB laser diode and the optical filter chip are supported on the thermo-electric cooler and wherein the light from the tunable laser diode or a fraction thereof is directed through the tunable optical filter.

In another aspect, the invention pertains to a method for wavelength locking a distributed feedback (DFB) laser, the method comprising:
adjusting an output wavelength of the DFB laser based on the output of a photodetector receiving a portion of the laser light after passing through a tunable optical filter, wherein the optical filter is maintained with peak output at a selected wavelength range by monitoring its temperature and adjusting a thermal phase adjuster based on a previous calibration of the filter, the DFB laser comprising an adjustable gain medium current and/or a resistive heater.

The above summary is not intended to describe each illustrated embodiment or every implementation of the present disclosure.

### BRIEF DESCRIPTION OF THE SEVERAL VIEWS OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 depicts a schematic top-down view of a DFB tunable laser unit that includes a tunable optical filter chip interfaced with a tunable laser diode, according to one or more embodiments of the disclosure, in which an optical filter structure is in line with the laser light output pathway.

FIG. 2 depicts a schematic side view of the DFB tunable laser unit of FIG. 1 that functionally depicts the tunable optical filter chip and the tunable laser diode.

FIG. 3 is a side view of the tunable laser device of FIG. 1 depicting the layered structure of a silicon photonics chip used for the tunable filter chip.

FIG. 4 is a schematic fragmentary top view of a tunable optical filter based on a Mach-Zehnder interferometer based delay line optical filter with a thermal resistive heater for tuning the filter.

FIG. 5 depicts a diagram showing a simulated transmission profile for a tunable laser component, according to the tunable laser device of FIG. 1.

FIG. 6 is a flow diagram depicting a method of wavelength stabilization, according to one or more embodiments of the disclosure.

FIG. 7 depicts a schematic side view of an alternative embodiment of a tunable laser device that functionally depicts the tunable laser component and the tunable laser diode, according to one or more embodiments of the disclosure, in which a tunable optical filter structure receives light from a tap with the optical filter structure off the laser light output pathway.

FIG. 8 depicts a schematic top view of the tunable laser device of FIG. 7 showing the integration of the optical filter structure in the tunable optical filter chip.

FIG. 9 depicts a diagram showing a stimulated transmission profile for a tunable laser component with a 50 GHz free spectral range, according to one or more embodiments of the disclosure.

FIG. 10 depicts a diagram showing a simulated DFB laser tuning curve with temperature and laser current to lock at grid wavelengths, according to one or more embodiments of the disclosure.

FIG. 11 depicts a diagram showing a simulated DFB laser's 2D tuning map of temperature and laser current to lock at grid wavelength and power, according to one or more embodiments of the disclosure.

While the embodiments of the disclosure are amenable to various modifications and alternative forms, specifics thereof have been shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure.

### DETAILED DESCRIPTION

Various embodiments are directed to a distributed feedback (DFB) tunable laser unit for improved wavelength stabilization by adjusting the laser output wavelength for the maintenance of peak laser output at the desired wavelength. In one or more embodiments, the DFB tunable laser unit comprises a substrate, generally a thermoelectric cooler supporting a tunable laser diode and a semiconductor filter chip with a tunable optical filter, a heater for tuning the optical filter, and an integrated resistance temperature device (RTD) for measuring temperature, in which the optical filter is used to provide wavelength control to keep the DFB tunable laser locked to a target wavelength set on the filter. The filter chip can be conveniently formed using silicon photonics that can be appropriately optically attached to the laser diode. The optical filter component of the optical chip can be formed with the optical filter in line with the laser output with a tap to sample the filter output or with the optical filter configured to receive a sample of laser light from a tap on the laser output waveguide. In such embodiments, the RTD is used to monitor the temperature of the tunable optical filter, which is input into a feedback loop coordinated with a controller for temperature control. When adjusting the laser output wavelength, a controller providing a dither signal to the DFB tunable laser and feedback loop can provide appropriate current to the DFB tunable laser to lock the target wavelength through the filter chip, thereby providing a stable wavelength of the DFB laser even with external thermal disturbance and/or gain chip aging.

Improved wavelength control of narrow output tunable DFB lasers can be useful for many network applications. As such, various embodiments herein enable wavelength tuning and control to maintain wavelength accuracy against perturbations, such as external environmental disturbances. Aging generally effects the laser diode output and tuning. In addition, various embodiments of the DFB tunable laser unit provide advantages of lower cost, lower power consumption, and a smaller footprint compared to designs with other structures to maintain the laser wavelength within acceptable ranges. Laser wavelength can equivalently be referenced in terms of laser frequency.

Temperature control can employ a thermo-electric cooler (TEC) and thermistor, the latter being located typically several millimeters from the laser's active region. However, this can create errors as the control system measures the temperature of the thermistor rather than the laser, thus is affected by changes to the temperature gradient between the thermistor and the active region, caused by changes to the external temperature over the specified temperature range. To improve the wavelength stability provided by thermistor control, several optical techniques are currently used. Thermally stable optical filters and etalons typically offer ˜1 GHz stability over the life and operating temperature range of the device and can be used in wavelength lockers. These lockers can either be either internal or external to the package, as a separate device. As such, these techniques inevitably increase the package component count (collimating optics, etalon, filter, beam splitter, PIN diodes, etc.) and require active optical alignment during assembly to ensure the laser output is aligned to the ITU grid.

Various embodiments herein involve improved designs and methods for accurately wavelength locking a DFB tunable laser. For example, one or more embodiments of a tunable DFB laser unit comprise a tunable optical filter, such as formed with silicon photonics, with attached resistive temperature device (RTD). In such embodiments the wavelength of a DFB tunable laser can be controlled accurately and reliably with the tunable semiconductor filter using a feedback loop based on external temperature changes and/or gain medium current changes. In particular, a heater associated with the laser diode and/or the current to the laser diode can be altered to adjust the laser output with its peak approximately at the desired wavelength.

Two alternative structures are described in which a first structure has an optical filter in line with the laser output pathway, and a second structure has an optical filter attached to a tap that samples a portion of laser output. The output of the optical filter is used to evaluate drift of the laser, in which the optical filter is tuned to the desired wavelength. A photodetector is used to evaluate maintenance of the laser output at the target wavelength. The use of a silicon photonics chip for providing the optical filter is compact and efficient.

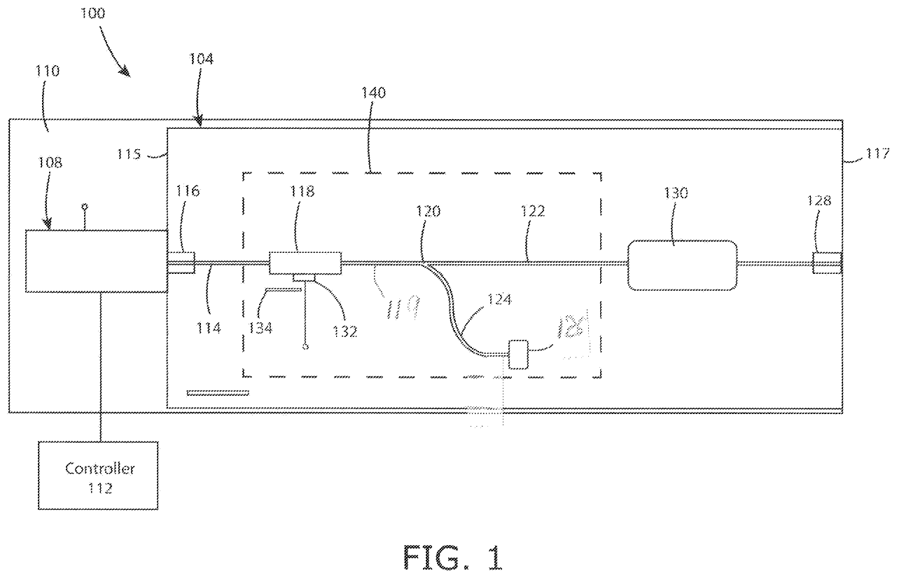

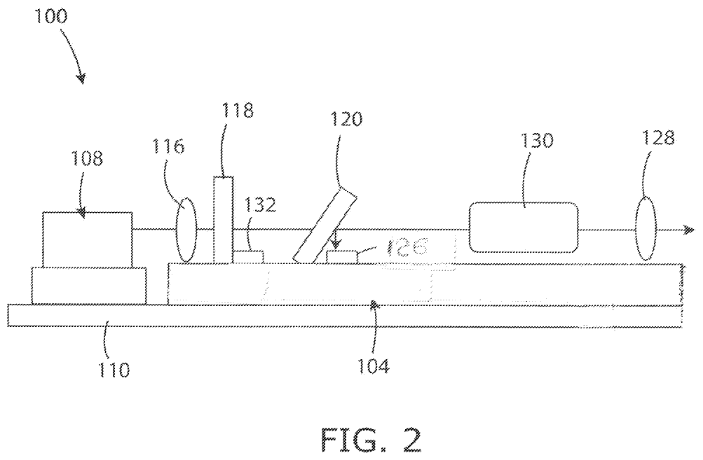

Referring to FIGS. 1-2, a tunable distributed feedback (DFB) laser unit 100 is depicted, with the optical filter in line with the laser output. In various embodiments, tunable DFB laser unit 100 comprises a tunable distributed feedback (DBF) laser diode 108. Tunable DFB laser diode 108 interfaces with an optical filter chip 104 that are connected by a spot size converter, such as first lens 116. In one or more embodiments, optical filter chip 104, and tunable DFB laser diode 108 rest on a temperature controller, such as a thermoelectric cooler (TEC) 110 that helps control the overall device temperature. In such embodiments the TEC 110 and the overall device temperature may be controlled with a logical controller 112. TEC components are known in the art. As depicted in FIG. 1, the laser device 108 and optical filter chip 104 are positioned on a shared TEC 110, although separate TEC can be used or alternative temperature control structures could be used. For convenience, the tunable distributed feedback (DFB) laser unit 100 with optical filter chip 104 and a tunable DBF laser diode 108 as well as TEC 110 (if present) generally would be assembled in a package. In one or more embodiments, optical filter chip 104 comprises a temperature sensor 134, such as a thermistor or the like, configured to sense filter temperature. In various embodiments, and described further below, temperature sensor 134 can be used to calibrate filter wavelength.

Tunable DFB laser diodes are generally formed from layered semiconductor structures. The diodes generally comprise a p-n junction, such as formed from indium phosphide, gallium arsenide, variations thereof involving III/V semiconductor materials and doped versions thereof, or other semiconductor material. An array of DFB lasers are described in U.S. Pat. No. 9,660,421 to Vorobeichik et al., entitled Dynamically-Distributable Multiple-Output Pump for Fiber Optic Amplifier,” incorporated herein by reference. Suitable tunable DFB laser diodes 108 are commercially available from Lumentum. DFB lasers are discussed further in published U.S. patent application 2002/0183002 to Vail et al., entitled “Switched laser Array Modulation With Integral Electroabsorption Modulator,” incorporated herein by reference. Tuning of a DFB laser can be based on, for example, use of a heater to alter the index of refraction of the optical materials or altering the driving voltage of the DFB laser, which shifts the band gap. A controller with feedback from the optical filter output can correspondingly make the tuning adjustments for the laser, such as based on a dithering of the current(s) to the laser diode.

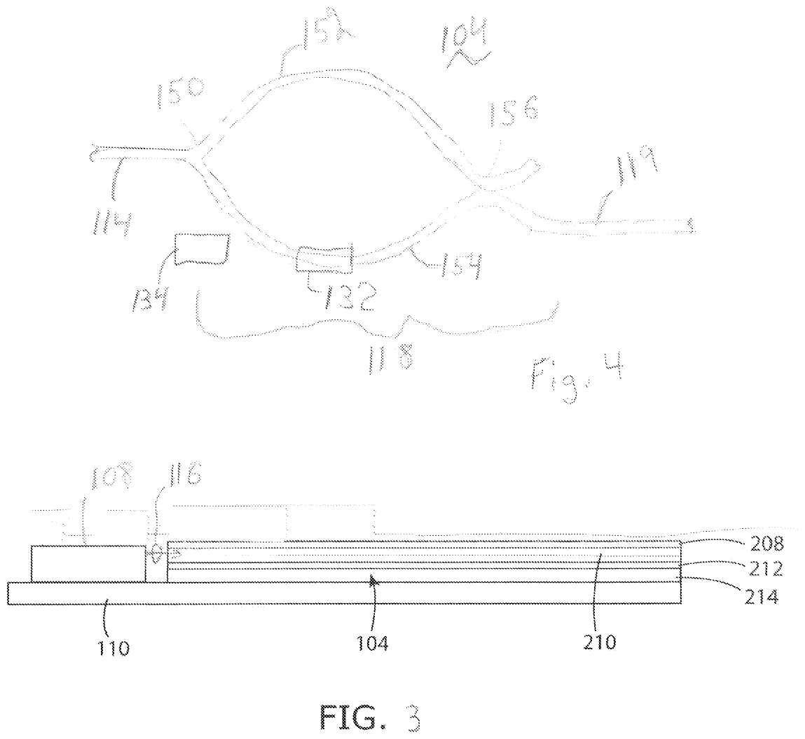

Referring to a specific embodiment in FIG. 3, optical filter chip 104 is a multi-layer silicon photonic chip comprising an upper cladding layer 208, a silicon device layer 210, a lower cladding layer 212, and a silicon substrate 214. In various embodiments, the layers are arranged where the upper cladding layer 208 forms a top layer with the silicon device layer 210 being located between the upper cladding layer 208 and the lower cladding layer 212. In one or more embodiments, the lower cladding layer 212 is located on the silicon substrate 214, which forms a bottom portion of optical filter chip 104.

In one or more embodiments, the upper cladding layer 208 and the lower cladding layer 212 are silicon oxide layers, although other low index of refraction optical material can be used in addition to or in lieu of silicon oxide. As used herein, the term silicon oxide refers generally to silicon dioxide or silicon suboxides with different oxidation states. For example, the term silicon oxide includes both silicon monoxide (SiO) and silicon dioxide (SiO₂). In various embodiments, the cladding layers thickness above and below the device layer generally can range from about 0.3 microns to about 3 microns.

In one or more embodiments the silicon device layer 210 is a patterned layer comprising regions of elemental silicon surrounded by silicon oxide as cladding along with metalized or other components to form one or more “devices” such as waveguides, filters, optical taps, temperature sensors, thermoelectric resistive heaters, and the like. For example, silicon photonic chips generally comprise one or more silicon waveguides of elemental silicon, potentially with a dopant, that is embedded as cladding in a layer of silicon oxide, such as silicon dioxide (SiO₂). In various embodiments, one or more cladding layers confine the light in the silicon waveguide due to an index of refraction difference. Waveguides and other structures for the silicon photonic chips can be formed using photolithography or other appropriate patterning technique, such as those known in the art. When utilizing a silicon oxide cladding, the processing can adapt techniques from silicon on insulator processing for microelectronics. Due to the high index of refraction of silicon, the silicon waveguide can have a thickness of about 0.2 microns to about 0.5 microns. In one or more embodiments, optical filter chip 104 has a package size of approximately 90 microns thick. The silicon photonics chip can be metalized to provide resistive heaters for the optical filter tuning and for forming temperature sensors. Metallization can also be performed using photolithography.

Referring to FIG. 1, in various embodiments, optical filter chip 104 comprises a silicon photonic chip extending from a first end 115 to a second end 117, a spot size converter 116, a tunable optical filter 118, an optical tap 120 splitting the waveguide 114 between a first waveguide portion 122 and a second waveguide portion 124, a first photodetector 126 configured to receive light from the second waveguide portion 124 from the optical tap 120, and an optional second spot size converter 128. A first waveguide segment 114 connects spot size converter 116 with tunable optical filter 118, and second waveguide section 119 connects tunable optical filter 118 with optical tap 120. The continuing light output from optical tap 120 continues in output waveguide 122. In certain embodiments, optical filter chip 104 additionally comprises an optical isolator 130. Optical isolators can be formed in a silicon photonics chip. See, for example, Doerr et al., “Silicon Photonics Broadband Modulation-Based Isolator,” Optics Express, 2014 Feb. 24, Vol. 22(4), 4493-8, and Kittlaus et al., “Low-Loss Nonlinear Optical Isolators in Silicon,” Nature Photonics, 29 May 2020, Vol. 14, 238-239, both of which are incorporated herein by reference.

In various embodiments, the optical tap 120 is configured to split the waveguide 120 into the first waveguide portion 122 and second waveguide portion 124, in which a fraction of the beam intensity is directed into second waveguide portion 124. In various embodiments, optical tap 120 can have the form of an asymmetric splitter having one or both the first and second waveguide portions 122, 124 having a curved section to branch the waveguides away from each other further from optical tap 120. Optical tap 120 can be designed to tap off from about 1 percent to about 25 percent of the beam intensity, in further embodiments from about 2 percent to about 15 percent of the beam intensity for evaluation of the tuning. Generally, the second waveguide portion 124 is branched from optical tap 120 and is connected to first photodetector 126. First photodetector 126 can comprise a semiconductor diode structure integrated into the optical chip using techniques available to persons of ordinary skill in the art, although other photodetectors can be used as desired. In various embodiments, first waveguide portion 122 continues from optical tap 120 towards the second end (rear end) 117 of optical filter chip 104, opposite tunable DFB laser diode 108, and connected to second spot size converter 128, if used for conveying the optical beam to an optical fiber or other optical medium, although the waveguide can be connected to a further silicon photonic chip for laser transmission without necessarily involving a spot size converter. Described further below, in various embodiments, the first wave guide portion 122 can be further connected to optical isolator 130.

In one or more embodiments, first spot size converter 116 and second spot size converter (if present) 128 can comprise lenses designed to adjust the beam dimensions from one waveguide to another waveguide. In one or more embodiments, spot size converter 116 couples optical filter chip 104 to tunable DBF laser diode 108 and provide mode size matching to reduce loss due to the interface between optical filter chip 104 and tunable DFB laser diode 108. Appropriate lens alignment is known in the art. See, for example, published U.S. patent application 2005/0069261 to Arayama, entitled “Optical Semiconductor Device and Method of Manufacturing Same.” incorporated herein by reference. A multistage spot-size-converter is described in published U.S. patent application 2019//0170944 to Sodagar et al., entitled “Multistage Spot Size Converter in Silicon Photonics,” incorporated herein by reference.

As depicted in FIGS. 1 and 2, tunable optical filter 118 is coupled with the waveguide 114 and can be used to provide for frequency stabilization for tunable DFB laser diode 108 at the tuned frequency. In various embodiments, tunable optical filter 118 is tunable via thermal control and stabilized through monitoring of the temperature. In such embodiments, the filter can be associated with a heater 132 to provide for control of the filter response, which is correspondingly used to stabilize laser output at the selected frequency. In particular, thermal control can be used to control thermal fluctuations and thereby stabilize or otherwise control the filter output to keep the DFB tunable laser locked to a target wavelength.

Tunable optical filter 118 provides the reference frequency used for tuning the DFB laser. Tunable optical filter 118 can be any reasonable type of tunable filter design compatible with a silicon photonics architecture. For example, the tunable optical filter 118 could be a Mach-Zehnder interferometer (MZI), delay-line interferometer (DLI), ring resonator, etalon, or the like. A planar etalon structure is described in U.S. Pat. No. 11,487,068 to Vail et al., entitled “Adjustable Grid Tracking Transmitters and Receivers,” incorporated herein by reference. For example, a tunable filter design for a silicon photons chip is described in published U.S. patent application 2020/0280173 to Gao et al. (hereinafter the '173 application), entitled “Method for Wavelength Control of Silicon Photonic External Cavity Laser,” incorporated herein by reference. In the context of an optical modulator, a silicon photonics-based delay line interferometer (DLI) in an MZI configuration with a heater has been used to tune the DLI peak to the desired operation wavelength is described in published U.S. patent application 2016/0363835 to Nagarajan (hereinafter the '835 application), entitled “MZM Linear Driver for Silicon Photonics Device Characterized as Two-Channel Wavelength Combiner and Locker,” incorporated herein by reference.

As such, in various embodiments tunable optical filter 118 can comprise one or more subcomponents including splitters, combiners, temperature sensors, heaters, and the like. For example, in one or more embodiments, tunable optical filter 118 is associated with a temperature sensor 134. In certain embodiments the temperature sensor 134 is a resistance temperature detector (RTD) configured to measure temperature associated with tunable optical filter 118, within a particular temperature sensitivity.

An embodiment of tunable optical filter 118 in a silicon photonics chip 104 is shown schematically in FIG. 4. Tunable optical filter 118 in the embodiment of FIG. 4 has an optical splitter 150 receiving light from waveguide 114 and splitting the light into first branch waveguide 152 and second branch waveguide 154 on the form of a Mach-Zehnder interferometer. First branch waveguide 152 and second branch waveguide 154 meet at optical combiner 156 to provide a signal into second waveguide section 119. First branch waveguide 152 and second branch waveguide 154 may or may not have a common length. Heater 132 interfaces with second waveguide section 154 to contribute to the function of the Mach-Zehnder interferometer as a delay line interferometer, in which the heater can be used to tune the frequency of the optical filter. In such embodiments, tunable optical filter 118, in combination with heater 132 configured to tune tunable optical filter 118, can assist to stabilize or otherwise lock the wavelength of tunable DFB laser diode 108 to a specific frequency. For example, in various embodiments, tunable optical filter 118 is a component of a feedback loop where temperature changes or gain medium current changes associated with currents provided to DFB laser diode 108 are used in combination with readings from the RTD to accurately lock the wavelength of tunable DFB laser diode 108. The temperature measurement from the chip level RTD sensor can be used in the feedback loop for fixed frequency applications or to evaluate thermal control of the chip as well as reference heater currents.

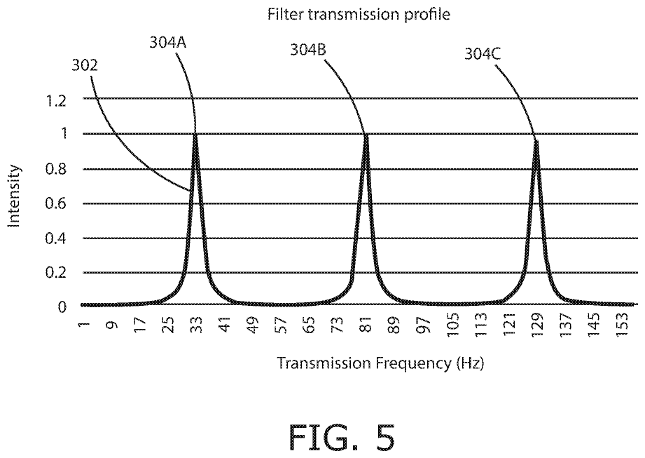

In a simulation based on the embodiment in FIG. 4, tunable optical filter 118 provided a free spectral range (FSR) of 500 GHz for example, to cover 300 GHz tuning range. Referring additionally to FIG. 5, a simulated transmission profile 302 is depicted for the optical filter chip component formed using silicon photonics in the configuration of FIG. 4. In this example embodiment, tunable optical filter 118 produces a filter transmission profile produces a plurality of peaks 304A, 304B, 304C, which provide the FSR.

In various embodiments, tunable optical filter 118 can be tuned using the heater to shift the peaks across the tuning range. After calibrating an actual embodiment of a silicon photonics based optical filter chip, the filter can be locked and monitored using the temperature sensor on the chip. The filter frequency should be fixed for the temperature, and the heater can be used to adjust for any temperature drift. The tap can be used to monitor any drift of the correlation of the laser frequency from the tuned filter frequency, as described further below.

For example, referring again to FIGS. 1-2, in one or more embodiments, tunable optical filter 118 and temperature sensor 134, and first photodetector 126 are used to monitor the temperature and/or output intensity from tunable optical filter 118 and provide that information to controller 112 as feedback for control of the laser frequency. As described further below, dithering of the laser frequency allows for the tuning of the laser frequency based on the optical filter output. In such embodiments the sensor data from temperature sensor 134 indicates the current frequency tuning of the filter output based on the temperature of the filter and surrounding waveguide. Similarly, the output from first photodetector 126 provides information on the alignment of the laser tuning and the filter frequency. If the laser is tuned to the same frequency as the optical filter, output of the photodetector is measured at its largest value, and any detuning of the laser relative to the optical filter results in a drop of the photodetector output. By dithering the laser frequency, the laser can be tuned to match the optical filter frequency, which results in the desired frequency locking effect. In such embodiments, this use of the optical filter provides a stable wavelength for tunable DFB laser diode 108, even with external thermal disturbance and gain chip aging.

Further, in various embodiments, the smaller thermal mass of the tunable optical filter allows the wavelength to lock faster and with less power expenditure than conventional TEC designs. Further, as described in various embodiments a secondary TEC and/or thermistor componentry are generally not required.

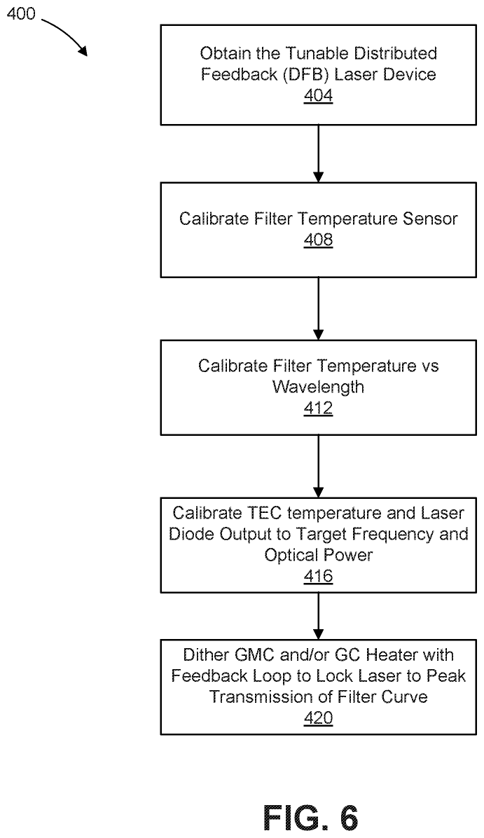

Referring to FIG. 6, a method 400 is depicted for wavelength locking utilizing the tunable distributed feedback (DFB) laser device 100 as described above. In one or more embodiments the method 400 comprises at operation 404, obtaining the tunable distributed feedback (DFB) laser device 100. In various embodiments, the method 400 comprises at operation 408, calibrating the temperature sensor 134. In particular, the RTD can be calibrated using a thermistor positioned on the TEC substrate to provide an accurate independent temperature reading, which can then be referenced to the sensor reading from temperature sensor 134 to provide a calibration correlating output from temperature sensor 134 to a temperature.

Then, at operation 412, method 400 comprises correlating filter temperature, evaluated with output of temperature sensor 134, with filter wavelength. In various embodiments, calibration of the filter using the relationship of temperature vs wavelength can be achieved using the calibrated temperature sensor along with a wavelength meter.

In one or more embodiments, method 400 comprises, at operation 416, calibrating TEC temperature and gain medium current of the laser diode to a target frequency and target optical power output. The calibration data can be used to formulate a fitting equation and/or a lookup table corresponding to 1) filter temperature versus wavelength, 2) output power versus photodiode reading, and/or 3) TEC temperature versus gain medium current. Steps 404 through 416 involve calibration of the laser diode device 100 prior to use. Then, the components are ready for operation in a frequency locked configuration. The silicon photonic temperature can be monitored using the sensor on the silicon photonics chip. The heater can be adjusted to maintain the tunable optical filter at the temperature to provide the filter frequency selected.

Upon receiving a customer tune command, the controller, using software and/or firmware, can set the filter temperature, TEC temperature and gain medium current to the target wavelength and output power based on the equation or look up table. After adjustments are settled, the gain medium current (diode current and/or gain chip heater current) can be dithered to lock the laser to the peak transmission of the optical filter to effectively lock the laser frequency and power output.

As well as reacting to a tune commend, during use of the laser diode device 100, it may be desirable to confirm that the frequency has not drifted. With the tunable optical filter integrated into the structure, the tapped light intensity provides a continuous output that is a fraction of the laser output from the device. When it is determined that the laser frequency should be adjusted to the locked wavelength, the laser diode frequency is dithered by scanning the voltage to the laser diode. The laser diode frequency can be adjusted using a resistive heater, the driving voltage or both. Dithering can comprise a linear stepping of the voltage or other reasonable pattern of stepping the values. The output of the tapped photodetector can be monitored as a function of the dither value. When the frequency of the laser output more closely matches the tunable optical filter frequency, the photodetector output increases. The value of the dithered voltage at the largest value of the photodetector output can be used to lock the laser that this frequency to provide the desired frequency locking.

To summarize the overall approach to the frequency locking procedure, the optical filter provides a more stable reference point to select and lock onto a desired frequency. While the optical filter is temperature sensitive, a suitable measurement of the temperature on the silicon photonic chip can provide an appropriate measure of the filter temperature, and heaters associated with the filter, can be used to adjust the temperature of the filter. A calibration curve for a specific heater can provide an accurate temperature value for the filter to achieve a target frequency. The DFB laser can be set to conditions to provide an approximate output frequency. The efficiency of the output of the laser light through the optical filter provides information on the laser output. At appropriate times, dithering of the laser adjustment scans the laser tuning such that when the optical filter output is at its highest value, this indicates that the laser is tuned appropriately close to the optical filter frequency. The laser driving parameters can then be locked at the tuned values to provide for the locked laser output conditions. The laser frequency locking can then be rechecked as desired, such as following frequency adjustment, when laser output dropped sufficiently, and/or at desired time intervals.

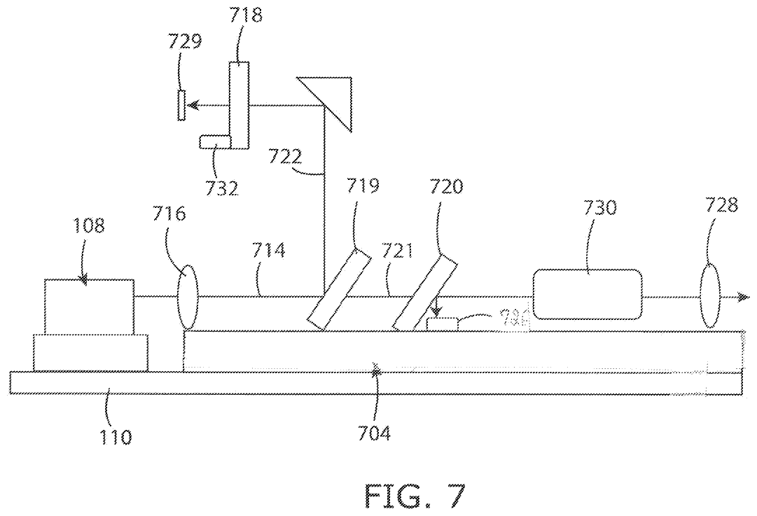

Referring to FIG. 7 a functional side view of another embodiment of a tunable distributed feedback (DFB) laser unit 700 is depicted, according to one or more embodiments. In various embodiments, laser device 700 comprises a tunable DBF laser diode 108 and an optical filter chip 704. In embodiments of particular interest, optical filter chip 704 is a silicon photonics chip with the basic structure as shown in FIG. 3. In the embodiment depicted in FIG. 7, within the structure provided by the plurality of layers schematically shown in the figure, optical filter chip 704 comprises a waveguide 714, a first lens 716, a first optical tap 719 splitting the waveguide 714 between a first waveguide portion 721 and a second waveguide portion 722, a second optical tap 720 splitting the waveguide 714 between a waveguide branch to a first photodetector 726 configured to receive light from second optical tap 720 and a second lens 728. In certain embodiments, the tunable laser component 704 additionally comprises an isolator 730 in the optical path from second optical tap 720 and second spot size converter 728. In various embodiments the design of the tunable laser component 704 is similar to tunable component 104 described above, and a description of the components found there can be considered part of the description of the corresponding component as if the words were explicitly copied here. However, in various embodiments the second waveguide portion 722 directs the optical signal to a tunable optical filter 718 and a second photodetector 729 configured to detect a secondary photodetector value in addition to the first photodetector 728, described above. In such embodiments, and in contrast with the embodiment described above in the context of FIG. 1, tunable optical filter 718 is positioned offset from the optical path through the component 704 as output. A heating element 732 is associated with tunable optical filter 718.

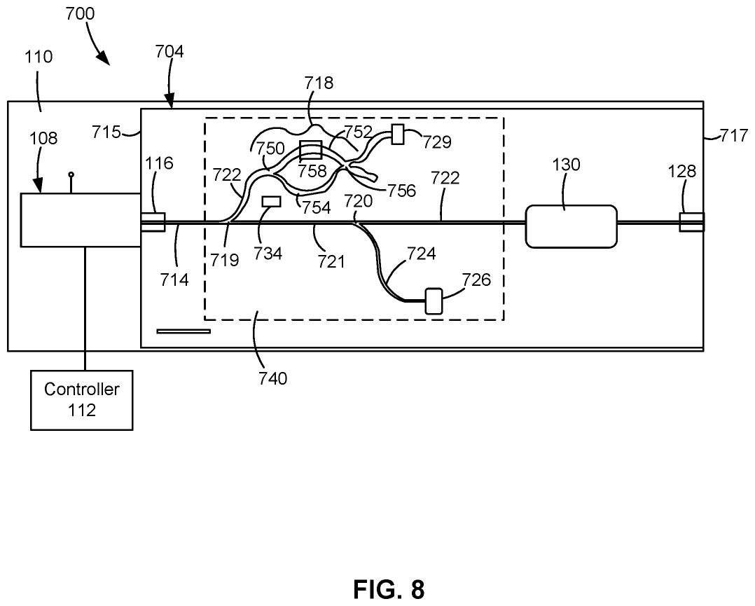

Referring to the top schematic view in FIG. 8, a temperature sensor 734 is attached to optical filter chip 704, and a secondary TEC and/or thermistor are not required to maintain a higher degree of temperature stability or adjustment. Comparing the top view in FIG. 8 with the corresponding view in FIG. 1, the devices are similar with optical filter chip 704 replacing optical filter chip 104, in which optical filter chip 704 differs from optical filter chip 104 with respect to the feedback portion 740 being different from feedback portion 140. Referring to FIG. 8, tunable optical filter 718 has a Mach-Zehnder interferometer based delay-line interferometer structure similar to the embodiment in FIG. 4. Tunable optical filter 718 comprises an optical splitter 750 connecting second waveguide portion 722 with first waveguide arm 752 and second waveguide arm 754. First waveguide arm 752 and second waveguide arm 754 converge at optical combiner 756. For the formation of a delay line structure, first waveguide arm 752 and second waveguide arm 754 may or may not have the same length, and generally first waveguide arm 752 is associated with a resistive heater 758 or the like, in which second waveguide arm 754 may or may not be associated with a heater. Resistive heater 758 can be used to tune the optical filter. Thus, this embodiment of the tunable DFB laser device has the advantage of size, power consumption and cost, similar to the first design. In various embodiments, the wavelength can be characterized to the secondary photodetector (PD) value or ratio of the second photodetector 729 to the first photodetector 728.

The frequency locking of the tunable DFB laser device 700 can be performed following the method shown in FIG. 6 with appropriate adjustment for the different device design. In particular, the calibration follows closely for tunable DFB laser device 700 using the output photodetector 729, although another alternative is to use the ratio of the photo detector output from photodetector 629 divided by the output form photodetector 726. Photodetector 729 output or ratios of the outputs of photodetector 729 divided by the output of photodetector 726 provides the desired information for locking the frequency of laser diode 108 based on dithering the frequency as described above for FIG. 1, which is correspondingly applicable here also. Photodetector 726 also provides separate information relating to laser power output. Calibration for this embodiment can also involve an equation or look up table of output power as a function of output of photodetector 726, in addition to filter temperature versus wavelength and TEC temperature versus gain medium current.

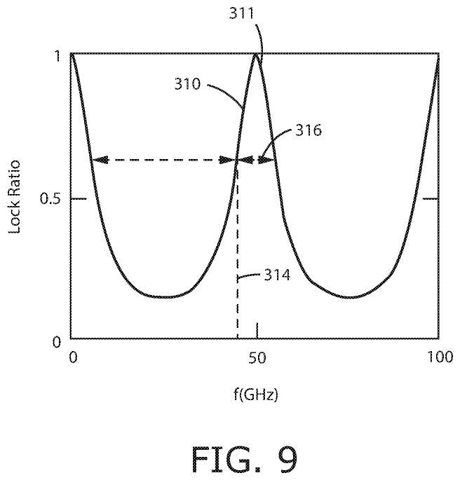

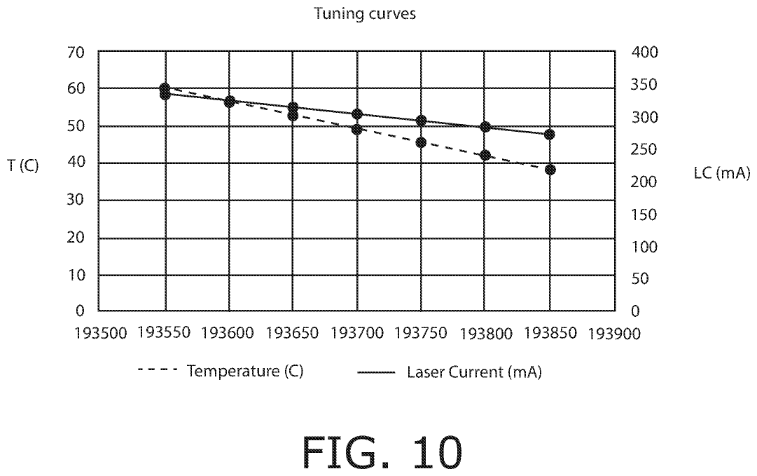

Simulations were also performed with tunable DFB laser device of FIGS. 7 and 8, With this embodiment, a transmission profile of the filter had a 50 GHz FSR, as shown in FIG. 9, based on a 850 micron thick silicon structure. Comparing FIG. 9 with FIG. 6, the transmission profile in FIG. 9 has a FSR value that is a tenth of the value in FIG. 6. Referring additionally to FIG. 9, a simulated transmission profile 310 is depicted for the optical filter chip component. In one or more embodiments the component produces a filter transmission profile produces a peak 311 having a lock frequency 314 that spans a lock margin 316. A tuning table can correlate the temperature and laser current parameters to lock grid wavelength and power, and an Example is presented in Table 1. These numbers are plotted on a tuning curve in FIG. 10.

In general, a filter design with a larger value of FSR can provide a greater tuning range. Correspondingly, a filter design with a smaller value of FSR can provide for a faster laser adjustment with a smaller difference between the laser wavelength and the selected filter wavelength. In some embodiments, the tunable optical filter can have an FSR from about 5 GHz to about 5000 GHz and in some embodiments form about 10 GHz to about 2500 GHz. A person of ordinary skill in the art will recognize that additional ranges of FSR within the explicit ranges above are contemplated and are within the present disclosure.

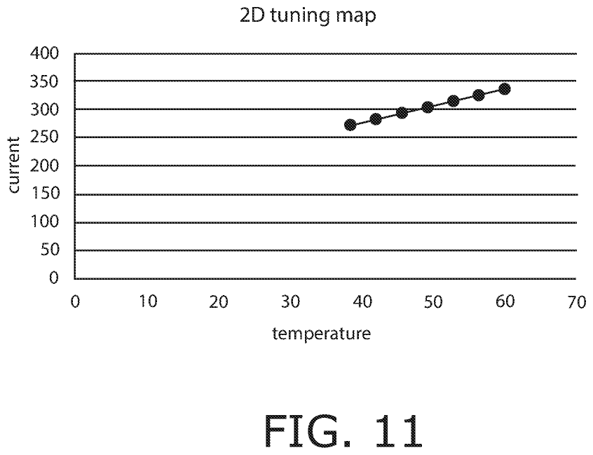

Referring specifically to FIG. 11, an example 2D tuning map depicts temperature and laser current curve to lock at a specific grid wavelength and power, which could be applicable to any embodiment of the laser device. In various embodiments, during calibration at a selected calibration point, the gain medium current can be dithered to lock to the peak of the filter curve.

TABLE 1

| | Frequency | Temperature | Laser |
|---|---|---|---|
| ITU Channel | (GHz) | (C.) | Current (mA) |
| Grid 1 | 193550 | 60.01 | 336.10 |
| Grid 2 | 193600 | 56.42 | 325.68 |
| Grid 3 | 193650 | 52.83 | 315.26 |
| Grid 4 | 193700 | 49.24 | 304.83 |
| Grid 5 | 193750 | 45.65 | 294.41 |
| Grid 6 | 193800 | 42.06 | 283.99 |
| Grid 7 | 193850 | 38.46 | 273.57 |

In various embodiments, calibration can be implemented using a fitting equation or a look-up table (with appropriate interpolation/extrapolation) of filter temperature vs wavelength, output power vs photodiode, and/or TEC temperature vs gain medium current. In one or more embodiments, software and/or firmware in the controller 112 or other component of the device can set the Filter temperature, TEC temperature and Gain Medium Current to target wavelength and output power based on the fitting equations or look-up table. The calibration resolution can be selected to provide the desired tuning accuracy.

In one or more embodiments, the method comprises dithering the gain medium current and/or the gain current heater with feedback loop to lock laser to the peak transmission of the filter curve. In various embodiments the DFB laser diode is now locked to target wavelength and optical power. As such, in various embodiments the DFB laser diode is locked without need for a second TEC, thermistor, or another component. This in turn provides significant advantages for power consumption, cost, and space. In various embodiments, at each calibration point, the filter temperature can be controlled using the RTD and heater so that laser is locked at inflection point of the filter curve. In one or more embodiments this can be done using the second photodetector and a filter heater dither. In some embodiments this can be done by dithering the gain medium current. In various embodiments this approach can also use locking at DC offset for fine tune frequency tuning of the wavelength. Another option is to use ratio of the second photodetector to the first photodetector to lock target wavelength (based on calibration). In various embodiments, calibration can be finalized using a fitting equation or a look-up table of filter temperature vs wavelength, output power vs photodiode, and/or TEC temperature vs gain medium current. In one or more embodiments, software and/or firmware in the controller 112 or other component of the device can set the Filter temperature, TEC temperature and Gain Medium Current to target wavelength and output power based on the fitting equations or look-up table.

In one or more embodiments, the method 400 includes, at operation 816, dithering the gain medium current and/or the gain current heater with feedback loop to lock laser to the peak transmission of the filter curve. In various embodiments the DFB laser diode is now locked to target wavelength and optical power. As such, in various embodiments the DFB laser diode is locked without need for a second TEC, thermistor, or another component. This in turn provides significant advantages for power consumption, cost, and space.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understand that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated. The use of the term “about” herein refers to measurement error for the particular parameter unless explicitly indicated otherwise.

What is claimed is:

1. A tunable distributed feedback (DFB) laser unit comprising
a thermo-electric cooler;
a tunable DFB laser diode; and
an optical filter chip comprising:
a tunable optical filter;
a first optical splitter with an optical tap and an output path, and
a first photodetector configured to receive light from the optical tap from the first optical splitter and to monitor output intensity from the tunable optical filter;
wherein the tunable DFB laser diode is supported on the thermo-electric cooler and wherein the light from the tunable laser diode or a fraction thereof is directed through the tunable optical filter.

2. The tunable DFB laser unit of claim 1, wherein the optical filter chip is supported on the thermo-electric cooler.

3. The tunable DFB laser unit of claim 1, wherein the optical filter chip further comprises a temperature sensor configured to sense a filter temperature for the tunable optical filter.

4. The tunable DFB laser unit of claim 1, wherein the optical filter chip further comprises a spot size converter configured to couple the optical filter chip to the tunable DFB laser diode.

5. The tunable DFB laser unit of claim 1, wherein the optical filter chip includes a silicon photonic chip extending from a first end to a second end, the silicon photonic chip including an upper cladding layer, a silicon device layer, a lower cladding layer, and a silicon substrate, wherein the silicon device layer is located between the upper cladding layer and the lower cladding layer.

6. The tunable DFB laser unit of claim 1, further comprising a logical controller coupled with the tunable DFB laser diode and the optical filter chip, wherein the optical filter chip is configured to provide laser frequency information to the logical controller as feedback for control of a laser frequency of the tunable DFB laser diode.

7. The wavelength locking tunable distributed feedback (DFB) laser unit of claim 6, wherein the logical controller is configured to control the laser frequency to match an optical filter frequency for wavelength locking.

8. The tunable DFB laser unit of claim 6, wherein the laser frequency information includes one or more of temperature information for the tunable optical filter and output intensity from the tunable optical filter.

9. The tunable DFB laser unit of claim 6, wherein the logical controller is configured to provide a dithering of the current(s) to the laser diode for tuning adjustments for the laser.

10. The tunable DFB laser unit of claim 1, wherein the thermo-electric cooler includes a thermistor.

11. The tunable DFB laser unit of claim 10, wherein the optical filter chip further comprises a temperature sensor that is calibrated based a temperature output from the thermistor.

12. The tunable DFB laser unit of claim 1, wherein the tunable optical filter has a free spectral range (FSR) of 500 GHz to cover 300 GHz tuning range.

13. The tunable DFB laser unit of claim 1 wherein the tunable optical filter is positioned in line with an optical path from the tunable DFB laser diode to the first optical splitter.

14. The tunable DFB laser unit of claim 1 wherein the tunable optical filter is positioned to receive light from the optical tap of the first optical splitter and the first photodetector is positioned to receive light from the tunable optical filter.

15. The tunable DFB laser unit of claim 14 further comprising a second photodetector and a second optical splitter with an optical tap and an output path, wherein the second optical splitter is positioned to receive light from the output path of the first optical splitter and wherein the second photodetector is positioned to receive light from the tap of the second optical splitter.

16. The tunable DFB laser component of claim 4, wherein a ratio of the first photodetector to the second photodetector provides information of laser wavelength relative to the wavelength of the tunable optical filter.

17. A wavelength locking tunable distributed feedback (DFB) laser unit comprising:
a thermo-electric cooler;
a tunable DFB laser diode; and
an optical filter chip comprising:
a tunable optical filter;
a first temperature sensor configured to sense a filter temperature for the tunable optical filter;
a first optical splitter with an optical tap and an output path, and
a first photodetector configured to receive light from the optical tap from the first optical splitter and to monitor output intensity from the tunable optical filter; and
a logical controller coupled with the tunable DFB laser diode and the optical filter chip, wherein the optical filter chip is configured to provide one or more of the filter temperature and output intensity from the tunable optical filter to the logical controller as feedback for control of a laser frequency of the tunable DFB laser diode to match an optical filter frequency; and
wherein the tunable DFB laser diode and the optical filter chip are supported on the thermo-electric cooler and wherein the light from the tunable laser diode or a fraction thereof is directed through the tunable optical filter.

18. The wavelength locking tunable DFB laser unit of claim 16, wherein the logical controller is configured to provide a dithering of the current(s) to the laser diode for tuning adjustments for the laser for control of the laser frequency.

19. A method for wavelength locking a distributed feedback (DFB) laser, the method comprising:
adjusting an output wavelength of the DFB laser based on the output of a photodetector receiving a portion of the laser light after passing through a tunable optical filter, wherein the optical filter is maintained with peak output at a selected wavelength range by monitoring its temperature and adjusting a thermal phase adjuster based on a previous calibration of the filter, the DFB laser comprising an adjustable gain medium current and/or a resistive heater.

20. The method of claim 19, wherein the adjusting step comprises dithering the output wavelength by varying the gain medium current and/or the resistive heater with a feedback loop to lock the laser wavelength output to the peak transmission of the filter output.
